(19) United States
(12) Patent Application Publication
(10) Pub. No.: US 2026/0354247 A1
(43) Pub. Date: Nov. 5, 2026

(54) SEMICONDUCTOR DEVICE

(71) Applicant: Mitsubishi Electric Corporation, Tokyo (JP)

(72) Inventor: Kazutoyo TAKANO, Fukuoka (JP)

(73) Assignee: Mitsubishi Electric Corporation, Tokyo (JP)

(21) Appl. No.: 19/531,743

(22) Filed: Feb. 6, 2026

(30) Foreign Application Priority Data
May 1, 2025 (JP) 2025-076112

(51) Int. Cl. H10W 72/59; H10D 30/66; H10D 62/10; H10D 64/62; H10D 64/66

(52) U.S. Cl. CPC H10W 72/59; H10D 30/668; H10D 62/124; H10D 64/62; H10D 64/665

(57) ABSTRACT

The present disclosure has an object of providing a semiconductor device with improved resistance to peeling of a bonding wire on a gate pad. A semiconductor device includes: a gate electrode facing a channel region through a gate oxide film; an interlayer insulating film covering the gate electrode; a source pad that is in electrical contact with a source layer and is insulated from the gate electrode by the interlayer insulating film; a gate line formed, through an insulating layer, on a region of a drift layer which does not overlap the source pad in a plan view; and a gate pad on the gate line through an insulating layer. An uneven shape of an upper surface of the gate pad differs in pitch from that of a lower surface of the gate pad.

### BACKGROUND

### Technical Field

The present disclosure relates to a semiconductor device.

### Description of the Background Art

A metal-oxide-semiconductor field-effect transistor (MOSFET) includes a semiconductor substrate including a drift layer, and includes a source pad and a gate pad formed on the semiconductor substrate. The source pad is a main electrode pad.

A base layer and a source layer are formed in a surface layer of a drift layer and immediately below the source pad. A region of the base layer between the source layer and the drift layer becomes a channel region. Gate electrodes are formed through respective gate oxide films at positions facing the channel region across a gate insulating film. An interlayer insulating film is formed on the semiconductor substrate to cover the gate electrodes and the gate oxide films. Since the interlayer insulating film is formed only at positions covering the gate electrodes, steps are formed between an upper surface of the interlayer insulating film and an upper surface of the semiconductor substrate on which the interlayer insulating film is not formed.

Japanese Patent Application Laid-Open No. 2002-305217 discloses an electrode pad formed on an interlayer insulating film. An uneven shape reflecting steps between the interlayer insulating film and an upper surface of a semiconductor substrate is formed in an upper surface of this electrode pad.

A source electrode (a source pad) is formed on the source layer and the interlayer insulating film. An uneven shape reflecting the steps between the interlayer insulating film and the upper surface of the semiconductor substrate is formed in the upper surface of this source pad.

Thus, when a wire bond is made to the source pad, bonding wires to be connected to the source pad are in contact with a plurality of protrusions of the steps in the upper surface of the source pad. Since energy of ultrasonic bonding locally concentrates on the protrusions of a small area, an oxide film on the source pad is destroyed to expose a clean surface, and bonding processes are started early at many portions.

On the other hand, immediately below a gate pad, an insulating film is formed on a drift layer or a flat P layer, and a gate line is formed on this insulating film. Another insulating film is formed on the gate line, and the gate pad is formed on this insulating film.

Since the gate line is typically flat, the insulating film formed on the gate line is also flat. Thus, the upper surface of the gate pad is flat in conformity with the shape of the insulating film immediately below the gate pad.

When a wire bond is made to the gate pad, the gate pad hardly undergoes the local concentration of the energy of ultrasonic bonding, unlike the source pad. Thus, when wire bonds are simultaneously made to the source pad and the gate pad in the same wire diameter and under the same bonding conditions, a process margin of the wire bond made to the gate pad is narrowed. This causes a problem in which the bonding wires tend to peel off.

While the MOSFET is exemplified above, the aforementioned problem also occurs in other semiconductor devices such as an insulated-gate bipolar transistor (IGBT).

### SUMMARY

The present disclosure has an object of providing a semiconductor device with improved resistance to peeling of a bonding wire on a gate pad.

The semiconductor device according to the present disclosure includes a drift layer of a first conductivity type, a base layer of a second conductivity type, a carrier supply layer of the first conductivity type, a gate electrode, an interlayer insulating film, a main electrode pad, a gate line, and a gate pad. The base layer is formed in a surface layer of the drift layer. The carrier supply layer is formed in a surface layer of the base layer. The gate electrode is disposed to face a channel region through a gate oxide film, the channel region being a region of the base layer between the carrier supply layer and the drift layer. The interlayer insulating film covers the gate electrode. The main electrode pad is in electrical contact with the carrier supply layer, the main electrode pad being insulated from the gate electrode by the interlayer insulating film. The gate line is formed on a region of the drift layer through an insulating layer, the region not overlapping the main electrode pad in a plan view. The gate pad is formed on the gate line through an insulating layer. The gate pad with an upper surface and a lower surface has an uneven shape in at least the upper surface. When the lower surface of the gate pad has an uneven shape, the uneven shape of the upper surface of the gate pad differs in pitch or phase from the uneven shape of the lower surface of the gate pad.

The gate pad of the semiconductor device according to the present disclosure has an uneven shape not in the lower surface but in the upper surface, or has an uneven shape in the lower surface and an uneven shape in the upper surface which differs in pitch or phase from that in the lower surface. Thus, the uneven shape of the upper surface of the gate pad can be brought closer to the uneven shape of the upper surface of the main electrode pad. Consequently, a process margin of a wire bond can be ensured, and peeling of a bonding wire on the gate pad can be suppressed.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 is a plan view of a semiconductor device;

FIG. 2 is a cross-sectional view of the semiconductor device including a source pad according to Embodiment 1;

FIG. 3 is a cross-sectional view of the semiconductor device including a gate pad according to Embodiment 1;

FIG. 4 illustrates a contact surface of a bonding wire with the gate pad;

FIG. 5 illustrates a contact surface of a bonding wire with the gate pad;

FIG. 6 is a cross-sectional view of a semiconductor device including a gate pad according to Embodiment 2;

FIG. 7 is a perspective view of a gate pad of a semiconductor device according to Embodiment 3;

FIG. 8 is a cross-sectional view of a semiconductor device including a source pad according to Embodiment 4; and

FIG. 9 is a cross-sectional view of the semiconductor device including a gate pad according to Embodiment 4.

### DESCRIPTION OF THE PREFERRED EMBODIMENTS

While this specification describes the first conductivity type as n-type and the second conductivity type as p-type on conductivity types of semiconductor layers, the conductivity types may be interchanged. In other words, the first conductivity type may be p-type, and the second conductivity type may be n-type.

### A. Embodiment 1

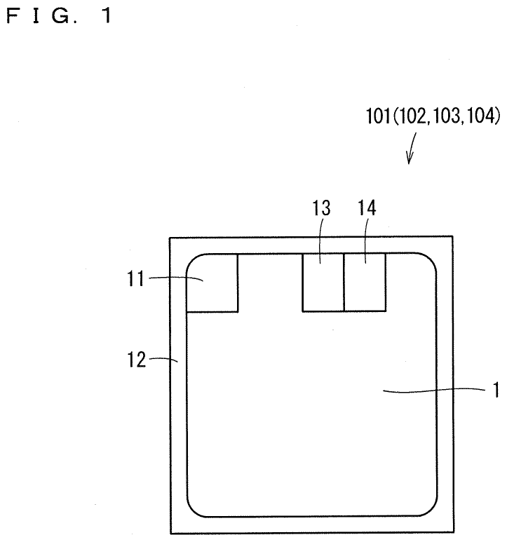

FIG. 1 is a top view of a semiconductor device 101 according to Embodiment 1. The semiconductor device 101 includes a source pad 1, a gate pad 11, an edge termination 12, a current sense pad 13, and a temperature sense pad 14.

While the semiconductor device 101 is described as a MOSFET in the following description, the semiconductor device 101 may be another semiconductor device such as an IGBT. When the semiconductor device 101 is an IGBT, an emitter pad replaces the source pad 1 in FIG. 1, and an emitter layer replaces a source layer 2. Here, the source pad and the emitter pad are example main electrode pads, and the source layer and the emitter layer are example carrier supply layers.

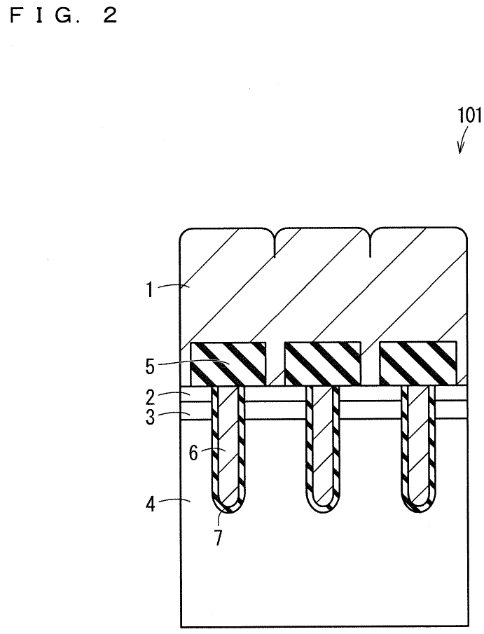

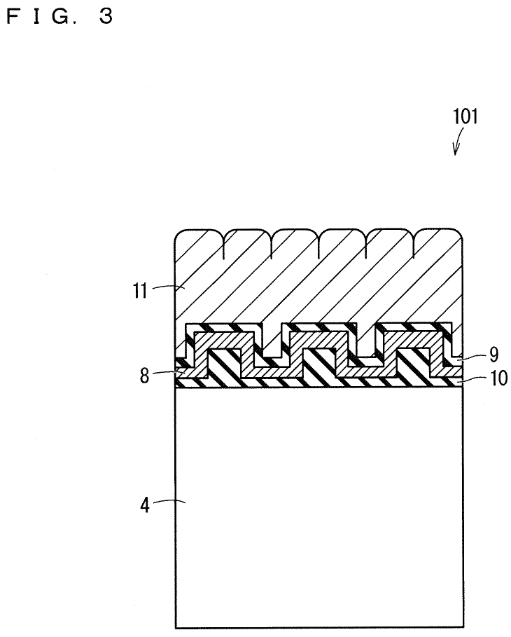

FIG. 2 is a cross-sectional view of the semiconductor device 101 including the source pad 1. In the semiconductor device 101, the source pad 1 including a structure immediately below the source pad 1 will be referred to as a source pad portion. FIG. 3 is a cross-sectional view of the semiconductor device 101 including the gate pad 11. In the semiconductor device 101, the gate pad 11 including a structure immediately below the gate pad 11 will be referred to as a gate pad portion.

The structure of the source pad portion will be hereinafter described with reference to FIG. 2. The semiconductor device 101 in the source pad portion includes an n-type drift layer 4, a p-type base layer 3, the n-type source layer 2, gate oxide films 7, gate electrodes 6, an interlayer insulating film 5, and the source pad 1. The source pad 1, which is made of, for example, aluminum, may be made of another material such as copper or an alloy of gold and nickel.

The base layer 3 is formed in a surface layer of the drift layer 4. The source layer 2 is formed in a surface layer of the base layer 3. A plurality of trenches penetrating the source layer 2 and the base layer 3 to reach the drift layer 4 are formed. The gate electrodes 6 are buried inside these trenches through the gate oxide films 7. A region of the base layer 3 in contact with the gate oxide films 7 between the source layer 2 and the drift layer 4 is a channel region. The gate electrodes 6 face the channel region through the gate oxide films 7.

The interlayer insulating film 5 is provided on the gate electrodes 6. The source pad 1 is provided on the interlayer insulating film 5. Contact holes exposing the source layer 2 are formed in the interlayer insulating film 5. The source pad 1 is in electrical contact with the source layer 2 through these contact holes. Steps are formed between the upper surface of the interlayer insulating film 5 and the upper surface of the source layer 2 which is exposed from the contact holes of the interlayer insulating film 5. Since the source pad 1 is formed along these steps, the lower surface of the source pad 1 naturally has an uneven shape.

Since the source pad 1 is generally formed by sputtering, the steps of a base (the source layer 2 and the interlayer insulating film 5) are also reflected in the upper surface of the source pad 1. In other words, the source pad 1 has an uneven shape also in its upper surface.

Next, a structure of the gate pad portion will be described with reference to FIG. 3. The semiconductor device 101 in the gate pad portion includes the n-type drift layer 4, a gate line 8, an insulating layer 9, an insulating layer 10, and the gate pad 11. The drift layer 4 is shared between the source pad portion and the gate pad portion. The gate pad 11, which is made of, for example, aluminum, may be made of another material.

The gate line 8 is provided on the drift layer 4 through the insulating layer 10. The gate pad 11 is provided on the gate line 8 through the insulating layer 9. The gate line 8 is not a flat plate but has a wavy shape. In other words, the upper surface and the lower surface of the gate line 8 have respective uneven shapes. The upper surface of the insulating layer 9 also has an uneven shape in conformity with the uneven shape of the upper surface of the gate line 8.

The gate pad 11 formed on the insulating layer 9 has an uneven shape in its lower surface in conformity with the uneven shape of the insulating layer 9 as a base.

The uneven shape of the upper surface of the gate pad 11 differs from that of the lower surface in at least one of pitch and phase. Since the gate pad 11 is generally formed by sputtering similarly to the source pad 1, the uneven shape of the upper surface of the gate pad 11 coincides with that of the lower surface of the gate pad 11 in pitch and phase as it is. Then, the upper surface of the gate pad 11 formed by sputtering is molded through patterning. This results in formation of an uneven shape in the upper surface of the gate pad 11 which differs in at least one of pitch and phase from that of the lower surface.

Alternatively, forming an unevenness smoothing layer on the insulating layer 9 and forming the gate pad 11 on the unevenness smoothing layer may suppress the unevenness in the upper surface of the gate pad 11 with respect to that in the lower surface. The unevenness smoothing layer is a conformal film formed with a uniform film thickness along the unevenness of the insulating layer 9, and corresponds to, for example, a barrier metal. The unevenness smoothing layer is formed with a uniform film thickness along the unevenness of the insulating layer 9. This reduces the size of the depressions in the upper surface of the unevenness smoothing layer by a film thickness of the unevenness smoothing layer. Consequently, the depressions of the upper surface of the gate pad 11 are reduced.

FIGS. 2 and 3 omit the illustration of an n-type semiconductor substrate supporting the drift layer 4, and a drain electrode formed on the back surface of the semiconductor substrate.

The amplitude of the unevenness formed in the upper surface of the gate pad 11 is greater than that naturally formed of grains in the gate pad 11. Here, the amplitude of the unevenness indicates a difference in height between a bottom of a depression and an upper surface of a protrusion. For example, the amplitude of the unevenness formed in the upper surface of the gate pad 11 is 10 nm or more.

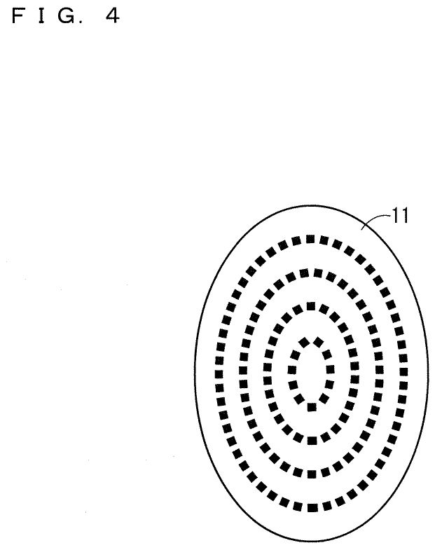

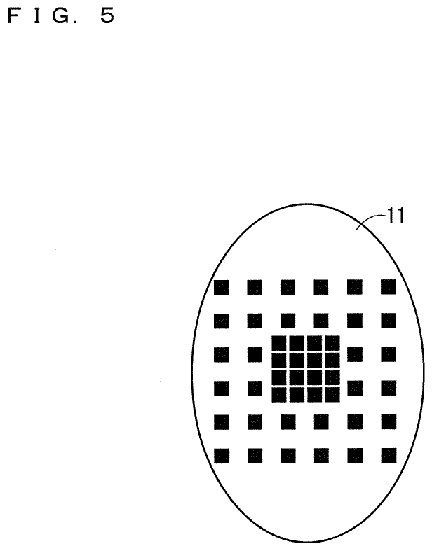

The unevenness of the upper surface of the gate pad 11 is desirably formed with certain regularity. FIGS. 4 and 5 each illustrate a wire bonding region of the upper surface of the gate pad 11. In these drawings, an oval outer frame indicates a contour of a contact surface of a bonding wire. Furthermore, small black rectangles each indicate a protrusion in the upper surface of the gate pad 11.

As illustrated in FIG. 4, the protrusions may be concentrically formed. As illustrated in FIG. 5, the protrusions may be formed in a lattice pattern. Furthermore, a density of the protrusions may be higher at the center of a contact region with the bonding wire and lower in the outer circumferential portion.

The upper surface and the lower surface of each of the current sense pad 13 and the temperature sense pad 14 are similar to those of the gate pad 11. The current sense pad 13 and the temperature sense pad 14 are not essential constituents for the semiconductor device 101.

The semiconductor device 101 includes: the drift layer 4 of the first conductivity type; the base layer 3 formed in a surface layer of the drift layer 4; the source layer 2 formed in a surface layer of the base layer 3; the gate electrode 6 disposed to face the channel region through the gate oxide film 7, the channel region being a region of the base layer 3 between the source layer 2 and the drift layer 4; the interlayer insulating film 5 covering the gate electrode 6; the source pad 1 in electrical contact with the source layer 2, the source pad 1 being insulated from the gate electrode 6 by the interlayer insulating film 5; the gate line 8 formed, through the insulating layer 10, on a region of the drift layer 4 which does not overlap the source pad 1 in a plan view; and the gate pad 11 formed on the gate line 8 through the insulating layer 9. The gate pad 11 has uneven shapes in both the upper surface and the lower surface, and the uneven shape of the upper surface of the gate pad 11 differs in pitch or phase from the uneven shape of the lower surface of the gate pad 11.

The semiconductor device 101 includes an uneven shape in the upper surface of the gate pad 11, so that the shape of the upper surface of the gate pad 11 can be brought closer to the shape of the upper surface of the source pad 1. This can ensure a process margin when wire bonds are made to the gate pad 11 and the source pad 1 in the same wire diameter and under the same wire bonding conditions, and prevent the wire bond of the gate pad 11 from peeling off.

### B. Embodiment 2

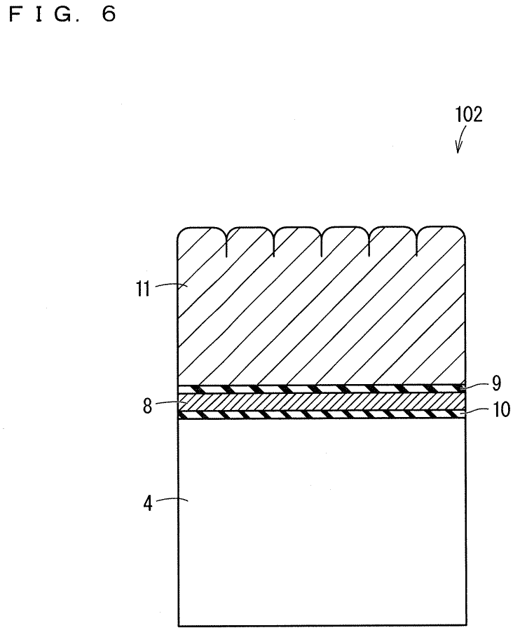

FIG. 6 is a cross-sectional view of a gate pad portion of a semiconductor device 102 according to Embodiment 2. In the gate pad portion of the semiconductor device 102, the lower surface of the gate pad 11 is flat, and the upper surface of the gate pad 11 has an uneven shape.

In the example of FIG. 6, the gate line 8 and the insulating layer 9 on the gate line 8 are flat. The gate pad 11 formed on the flat insulating layer 9 has a flat lower surface. The gate pad 11 formed by sputtering has a flat upper surface similarly to the lower surface. The gate pad 11 has an uneven shape only on its upper surface by patterning the upper surface of the gate pad 11 formed by sputtering.

FIG. 1 and FIG. 2 also illustrate the top view of the semiconductor device 102 and the cross-sectional view of the source pad portion, respectively.

The structure of the semiconductor device 102 can also bring the shape of the upper surface of the gate pad 11 closer to the shape of the upper surface of the source pad 1. This can ensure a process margin when wire bonds are made to the gate pad 11 and the source pad 1 in the same wire diameter and under the same wire bonding conditions, and prevent the wire bond of the gate pad 11 from peeling off.

### C. Embodiment 3

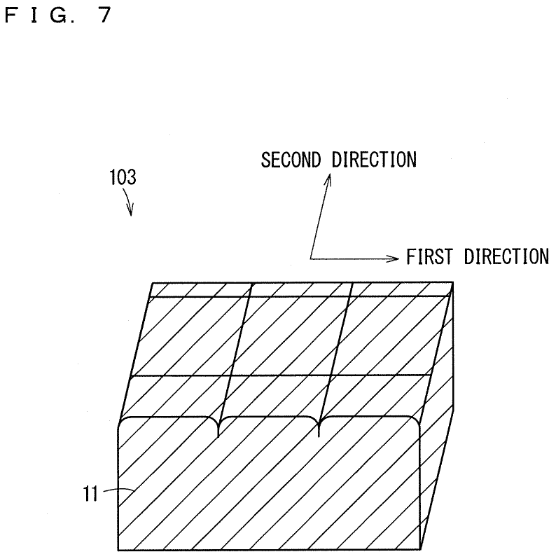

FIG. 7 is a perspective view of the gate pad 11 of a semiconductor device 103 according to Embodiment 3. FIG. 7 omits the illustration of a semiconductor substrate immediately below the gate pad 11.

In the semiconductor device 103, the upper surface of the gate pad 11 has a first uneven shape formed along a first direction, and a second uneven shape formed along a second direction different from the first direction. The second direction may be a direction orthogonal to the first direction.

In FIG. 7, the lower surface of the gate pad 11 is flat. The lower surface of the gate pad 11 may, however, have the first uneven shape formed along the first direction. Furthermore, the lower surface of the gate pad 11 may have the second uneven shape formed along the second direction, in addition to the first uneven shape.

In this case, the first uneven shape in the upper surface of the gate pad 11 coincide in pitch with the first uneven shape in the lower surface of the gate pad 11, and the second uneven shape in the upper surface of the gate pad 11 may differ in pitch from the second uneven shape in the lower surface of the gate pad 11.

The structure of the semiconductor device 103 can also bring the shape of the upper surface of the gate pad 11 closer to the shape of the upper surface of the source pad 1. This can ensure a process margin when the wire bonds are made to the gate pad 11 and the source pad 1 in the same wire diameter and under the same wire bonding conditions, and prevent the wire bond of the gate pad 11 from peeling off.

### D. Embodiment 4

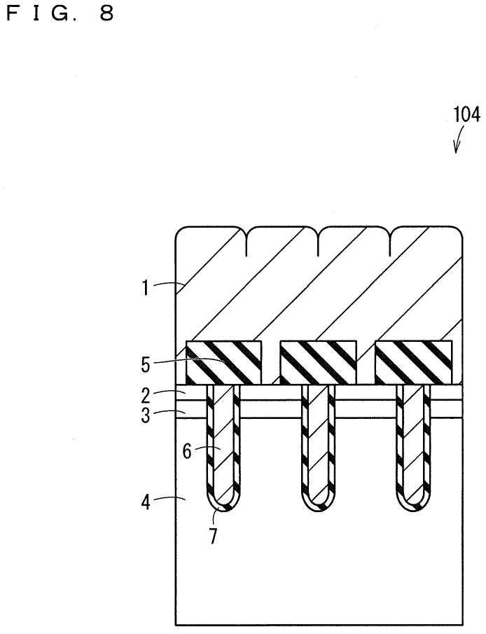

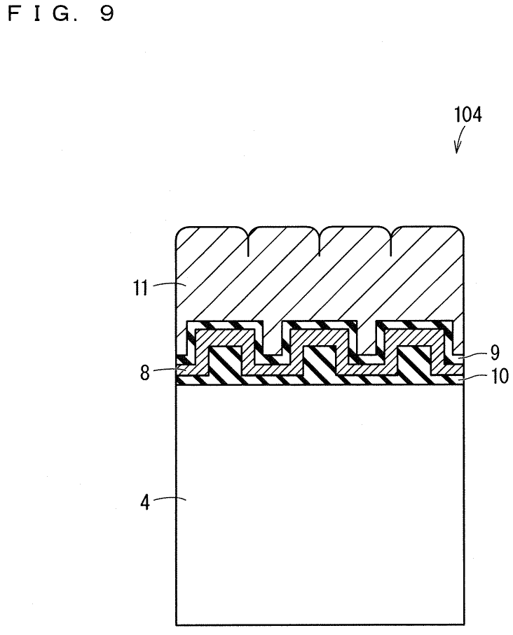

FIG. 8 is a cross-sectional view of a source pad portion of a semiconductor device 104 according to Embodiment 4. FIG. 9 is a cross-sectional view of a gate pad portion of the semiconductor device 104. FIG. 1 also illustrates the top view of the semiconductor device 104.

As illustrated in FIG. 8, an uneven shape identical in pitch but different in phase with respect to the uneven shape in the lower surface of the source pad 1 is formed in the upper surface of the source pad 1.

As illustrated in FIG. 9, an uneven shape identical in pitch but different in phase with respect to the uneven shape of the lower surface of the gate pad 11 is formed in the upper surface of the gate pad 11. Such uneven shape in the upper surface of the gate pad 11 is formed by simultaneously forming the source pad 1 and the gate pad 11 by sputtering and simultaneously patterning the upper surfaces of the source pad 1 and the gate pad 11.

The structure of the semiconductor device 104 can also bring the shape of the upper surface of the gate pad 11 closer to the shape of the upper surface of the source pad 1. This can ensure a process margin when the wire bonds are made to the gate pad 11 and the source pad 1 in the same wire diameter and under the same wire bonding conditions, and prevent the wire bond of the gate pad 11 from peeling off.

Furthermore, in the structure of the semiconductor device 104, depressions of the upper surface of the source pad 1 do not directly overlap the top of a region in which the source pad 1 is in contact with the source layer 2 through the contact holes of the interlayer insulating film 5 (hereinafter also referred to as a source contact region). In other words, a large thickness of the source pad 1 immediately above the source contact region can be ensured. This further attenuates the energy of ultrasonic bonding transferred to the source contact region in the wire bonding. Thus, damages to the source contact region can be suppressed, and the process margin in the wire bonding process can be ensured.

While, for example, preferred embodiments are described above in detail, various modifications and replacements can be added to, for example, Embodiments above without being limited to Embodiments and without departing from claims.

A summary of various aspects of the present disclosure will be hereinafter described as Appendixes.

Appendix 1

A semiconductor device, comprising:
a drift layer of a first conductivity type;
a base layer of a second conductivity type, the base layer being formed in a surface layer of the drift layer;
a carrier supply layer of the first conductivity type, the carrier supply layer being formed in a surface layer of the base layer;
a gate electrode disposed to face a channel region through a gate oxide film, the channel region being a region of the base layer between the carrier supply layer and the drift layer;
an interlayer insulating film covering the gate electrode;
a main electrode pad in electrical contact with the carrier supply layer, the main electrode pad being insulated from the gate electrode by the interlayer insulating film;
a gate line formed on a region of the drift layer through an insulating layer, the region not overlapping the main electrode pad in a plan view; and
a gate pad formed on the gate line through an insulating layer,
wherein the gate pad with an upper surface and a lower surface has an uneven shape in at least the upper surface, and
when the lower surface of the gate pad has an uneven shape, the uneven shape of the upper surface of the gate pad differs in pitch or phase from the uneven shape of the lower surface of the gate pad.

Appendix 2

The semiconductor device according to appendix 1,
wherein the lower surface of the gate pad is flat.

Appendix 3

The semiconductor device according to appendix 1 or 2,
wherein the uneven shape of the upper surface of the gate pad includes a first uneven shape formed along a first direction, and a second uneven shape formed along a second direction different from the first direction.

Appendix 4

The semiconductor device according to appendix 3,
wherein the gate pad has the uneven shape in the lower surface,
the uneven shape of the lower surface of the gate pad includes the first uneven shape formed along the first direction, and the second uneven shape formed along the second direction different from the first direction,
the first uneven shape of the upper surface of the gate pad coincides in pitch with the first uneven shape of the lower surface of the gate pad, and
the second uneven shape of the upper surface of the gate pad differs in pitch from the second uneven shape of the lower surface of the gate pad.

Appendix 5

The semiconductor device according to appendix 1,
wherein the uneven shape of the upper surface of the gate pad coincides in pitch and differs in phase with respect to the uneven shape of the lower surface of the gate pad.

Appendix 6

The semiconductor device according to any one of appendixes 1 to 5,
wherein the main electrode pad is a source pad, and
the carrier supply layer is a source layer.

Appendix 7

The semiconductor device according to any one of appendixes 1 to 6,
wherein the main electrode pad and the gate pad are made of aluminum.

What is claimed is:

1. A semiconductor device, comprising:
a drift layer of a first conductivity type;
a base layer of a second conductivity type, the base layer being formed in a surface layer of the drift layer;
a carrier supply layer of the first conductivity type, the carrier supply layer being formed in a surface layer of the base layer;
a gate electrode disposed to face a channel region through a gate oxide film, the channel region being a region of the base layer between the carrier supply layer and the drift layer;
an interlayer insulating film covering the gate electrode;
a main electrode pad in electrical contact with the carrier supply layer, the main electrode pad being insulated from the gate electrode by the interlayer insulating film;
a gate line formed on a region of the drift layer through an insulating layer, the region not overlapping the main electrode pad in a plan view; and
a gate pad formed on the gate line through an insulating layer,
wherein the gate pad with an upper surface and a lower surface has an uneven shape in at least the upper surface, and
when the lower surface of the gate pad has an uneven shape, the uneven shape of the upper surface of the gate pad differs in pitch or phase from the uneven shape of the lower surface of the gate pad.

2. The semiconductor device according to claim 1,
wherein the lower surface of the gate pad is flat.

3. The semiconductor device according to claim 1,
wherein the uneven shape of the upper surface of the gate pad includes a first uneven shape formed along a first direction, and a second uneven shape formed along a second direction different from the first direction.

4. The semiconductor device according to claim 3,
wherein the gate pad has the uneven shape in the lower surface,
the uneven shape of the lower surface of the gate pad includes the first uneven shape formed along the first direction, and the second uneven shape formed along the second direction different from the first direction,
the first uneven shape of the upper surface of the gate pad coincides in pitch with the first uneven shape of the lower surface of the gate pad, and
the second uneven shape of the upper surface of the gate pad differs in pitch from the second uneven shape of the lower surface of the gate pad.

5. The semiconductor device according to claim 1,
wherein the uneven shape of the upper surface of the gate pad coincides in pitch and differs in phase with respect to the uneven shape of the lower surface of the gate pad.

6. The semiconductor device according to claim 1,
wherein the main electrode pad is a source pad, and
the carrier supply layer is a source layer.

7. The semiconductor device according to claim 1,
wherein the main electrode pad and the gate pad are made of aluminum.
